(19) United States
(12) Patent Application Publication
(10) Pub. No.: US 2006/0157776 A1
(43) Pub. Date: Jul. 20, 2006

(54) System and method for contact module processing

(76) Inventors: Cheng-Hung Chang, Hsinchu (TW); Hsiao-Tzu Lu, Hsinchu (TW); Chu-Yun Fu, Taipei (TW); Weng Chang, Hsin-Chu (TW); Shwang-Ming Jeng, Hsin-Chu (TW)

Correspondence Address: SLATER & MATSIL, L.L.P., 17950 PRESTON ROAD, SUITE 1000, DALLAS, TX, 75252, US

(21) Appl. No.: 11/039,159

(22) Filed: Jan. 20, 2005

(51) Int. Cl. H01L 29/792

(52) U.S. Cl. 257/324

(57) ABSTRACT

System and method for improving the process performance of a contact module. A preferred embodiment comprises improving the process performance of a contact module by reducing surface variations of an interlayer dielectric. The interlayer dielectric comprises a plurality of layers, a first layer (for example, a contact etch stop layer 610) protects devices on a substrate from subsequent etching operations, while a second layer (for example, a first dielectric layer 620) covers the first layer. A third layer (for example, a second dielectric layer 630) fills gaps that may be due to the topography of the devices. A fourth layer (for example, a third dielectric layer 640), brings the interlayer dielectric layer to a desired thickness and is formed using a process that yields a very flat surface completes the interlayer dielectric. Using multiple layers permit the elimination of variations (filling gaps and leveling bumps) without resorting to chemical-mechanical polishing.

### TECHNICAL FIELD

The present invention relates generally to a system and method for manufacturing integrated circuits, and more particularly to a system and method for improving the process performance of a contact module.

### BACKGROUND

After the fabrication of devices in an integrated circuit has been accomplished, it becomes necessary to fabricate interconnections between the devices in order to produce a functioning integrated circuit. In a modern fabrication process, optical lithography techniques can be used in the creation of electrical contacts to the source/drain and gate terminals of the devices. The contacts need to pass through dielectric layers that can be used to passivate and isolate the devices.

However, the materials used in the dielectric layers can have different reflectivity properties depending upon their thickness and the wavelength of the light used in the optical lithography process. In order to maximize the accuracy of the lithography process, it is desired to minimize any variations in the reflectivity of the dielectric layer. Variations in the reflectivity of the dielectric material can result in inconsistent behavior in the light used in the lithography process. This inconsistent behavior can reduce precision with which the contacts can be cut through the dielectric layer. Since the reflectivity of the dielectric layer is a function of the thickness of the dielectric layer and the wavelength of the light (which is fixed for a given process), it is desired to make as constant as possible, the thickness of the dielectric layer.

One commonly used technique to minimize variations in the thickness of the dielectric layer is the use high-density plasma, chemical vapor deposition (HDP-CVD) to deposit a dielectric layer and then planarize the dielectric layer with a chemical-mechanical polisher (CMP). The chemical-mechanical polisher uses chemical (solvents) and physical (polishing media and surfaces) techniques to planarize the dielectric layer. Typically, a slurry (containing both chemical and physical polishing media) is applied to a wafer and then a polishing surface (usually a polishing wheel or belt) can be used to polish the wafer, planarizing the wafer in the process.

One disadvantage of the prior art is that while CMP can effectively planarize the wafer, the use of CMP can still result in wafers with a large degree of variation in the thickness of the dielectric layer. Furthermore, there can be a large variation in the thickness of the dielectric layer between different wafers. Additionally, the CMP process can be expensive due to the chemical and physical techniques used to planarize the wafers as well as the additional cleaning steps that are needed to cleanse the wafers after they undergo CMP.

A second disadvantage of the prior art is that HDP-CVD is not an effective technique for filling gaps between devices. The inability to fill the gaps between the devices can prevent the electrical isolation of the devices. This can result in an improperly working integrated circuit.

Another disadvantage of the prior art is that the use of HDP-CVD can result in damage to the devices due to electrical charge and ultra-violet (UV) light used in the HDP-CVD process. The use of HDP-CVD can also cause a loss in the thickness of the contact etch stop layer (CESL). A reduction in the thickness of the CESL can result in the inability of the CESL to stop chemical etch from damaging the devices, due to inadequate thickness.

Yet another disadvantage of the prior art is that the compression of the dielectric layer can result in the relaxation of the strained effect, thereby negating any gains in the driving current performance seen in the use of strained technology.

A further disadvantage of the prior art is that thickness measurements have to be made both before and after the use of the CMP process to ensure that the desired thickness of the dielectric layer is maintained. This is a result of the inability to precisely control the amount of dielectric material removed during the CMP process. For example, the amount of material removed in the CMP process can depend upon the condition of the polishing wheel since the polishing wheel's abrasiveness can decrease with use.

### SUMMARY OF THE INVENTION

These and other problems are generally solved or circumvented, and technical advantages are generally achieved, by preferred embodiments of the present invention which provides a system and method for improving the process performance of a contact module.

In accordance with a preferred embodiment of the present invention, a multilayer interlayer dielectric (MID) for a semiconductor device, wherein the semiconductor device comprises a field effect transistor (FET) and a substrate, is provided. The MID comprises a first thickness of the MID covering the FET and a second thickness of the MID over the first thickness of the MID, wherein a thickness ratio of the first thickness of the MID to the second thickness of the MID ranges from about 0.06 to about 0.90 and the MID further comprises a third thickness and a fourth thickness.

In accordance with another preferred embodiment of the present invention, a multilayer interlayer dielectric (MID) for a semiconductor device, wherein the semiconductor device comprises a field effect transistor (FET) and a substrate, is provided. The MID comprises a nitrogen containing layer over the FET and at least one oxygen-containing layer, wherein a thickness ratio of a thickness of the oxygen-containing layer to a thickness of the nitrogen containing layer ranges from about 1.1 to about 1.5 and the MID contains at least four layers.

In accordance with another preferred embodiment of the present invention, a method for fabricating a semiconductor device is provided. The method comprises forming a field effect transistor (FET) device on a semiconductor substrate followed by forming a first nitride layer over the semiconductor substrate, forming a first oxide layer over the first nitride layer, and forming a second oxide layer over the first oxide layer. The method further comprises computing a thickness for a third oxide layer and forming the third oxide layer over the second oxide layer.

An advantage of a preferred embodiment of the present invention is that a more uniform planarization of the dielectric layer is possible than when CMP is used, both on a single wafer and across different wafers. This is due to the greater predictability and precision of the processes involved in the present invention.

A further advantage of a preferred embodiment of the present invention is that gaps between devices can be filled more effectively than with HDP-CVD. The better gap fill results in better isolation of devices.

Yet another advantage of a preferred embodiment of the present invention is that the improved driving current performance achieved through the use of strained technology is maintained.

Another advantage of a preferred embodiment of the present invention is that there is no reduction in the thickness of the CESL. With the CESL unaffected by the gap-fill process, the chance of damage occurring to the devices below the CESL during etching is greatly reduced. Thereby, the yield can be increased.

An additional advantage of a preferred embodiment of the present invention is that a thickness measurement after the fabrication of the dielectric layer is no longer necessary. The elimination of the thickness measurement can result in a more rapid integrated circuit fabrication process and a reduction in the fabrication costs.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a data plot of the impact of variations in the thickness of a contact stop etch layer and an interlayer dielectric layer on the optical reflectivity of the layers;

FIG. 2 is a flow diagram of a prior art process for planarizing an interlayer dielectric layer;

FIGS. 3a and 3b are diagrams of cross sectional views of a substrate with an interlayer dielectric layer, shown pre and post planarization using the prior art planarization process shown in FIG. 2;

FIG. 4 is a data plot of interlayer dielectric layer thicknesses for a number of wafers using the prior art planarization process shown in FIG. 2;

FIG. 5 is a flow diagram of a process for planarizing an interlayer dielectric layer to help minimize surface variations, according to a preferred embodiment of the present invention;

FIGS. 6a through 6e are diagrams of cross sectional views of a substrate showing various steps in the formation of an interlayer dielectric layer with minimized surface variations, according to a preferred embodiment of the present invention; and

FIG. 7 is a flow diagram of a process for fabricating a semiconductor device with minimized surface variations, according to a preferred embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely the fabrication of a contact module in an integrated circuit, wherein there is a desire to maximize planarization of a dielectric layer. The invention may also be applied, however, to the fabrication of other layers in an integrated circuit wherein there is a desire to minimize variations in the thickness of the layers.

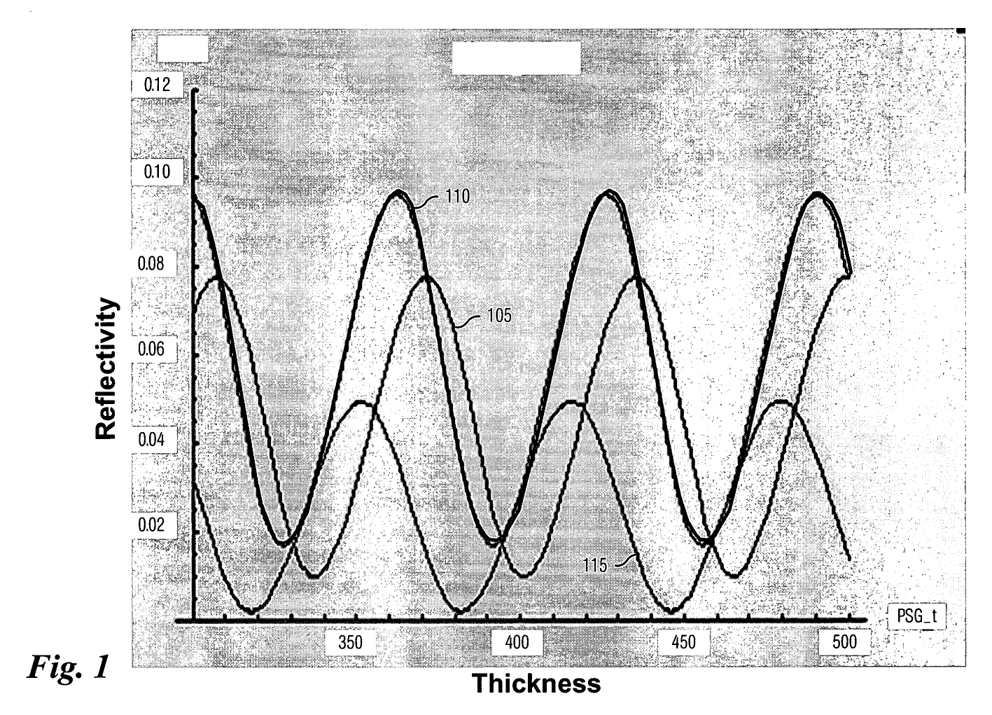

With reference now to FIG. 1, there is shown a data plot illustrating the impact of variations in the thickness of a contact stop etch layer (CESL) and an interlayer dielectric (ILD) layer on the optical reflectivity of the layers. As discussed previously, the optical reflectivity of a material used in a particular layer can be dependent upon the wavelength of the light being used and the thickness of the particular layer as well as the material itself. However, the presence of a layer beneath the particular layer can also have an effect upon the optical reflectivity. Furthermore, the thickness of the layer can also have an impact upon the optical reflectivity of the particular layer. For example, in an integrated circuit, a phosphorous-doped silicon glass (PSG) layer can be fabricated over a CESL layer for use as an interlayer dielectric layer. The optical reflectivity of the PSG layer is crucial since portions of the PSG layer will be removed in order to create electrical contacts for use in interconnecting devices fabricated in the integrated circuit. However, if there are variations in the thickness of the PSG layer as well as the CESL layer, the reflectivity of the PSG layer can vary, which can lead to inaccuracies in the placement, sizing, depth, and so forth of the portions of the PSG layer that is to be removed for the formation of the contacts and possibly leading to malformed, malfunctioning, and/or improperly placed electrical contacts.

The data plot shown in FIG. 1 shows three curves illustrating the reflectivity of a PSG layer as a function of thickness of the PSG layer, wherein each of the three curves represents a different thickness of a CESL layer. A first curve 105 represents a situation wherein the CESL is 20 nm (nano-meters) in thickness, a second curve 110 represents a situation wherein the CESL is 30 nm in thickness, and a third curve 115 represents a situation wherein the CESL is 40 nm in thickness. Clearly, the reflectivity of the PSG layer is dependent upon the thickness of the PSG layer. However, the data plot shown in FIG. 1 shows that the thickness of the CESL layer can have a significant impact upon the reflectivity of the PSG as well. For example, let the thickness of the PSG layer be 400 Å (angstroms), then the reflectivity of the PSG layer can vary from approximately 0.025 (when the CESL is 20 nm thick) to 0.015 (when the CESL is 30 nm thick) to 0.005 (when the CESL is 40 nm thick).

When the reflectivity of the PSG layer (the interlayer dielectric layer) can vary widely as both the function of the thickness of the PSG layer and the thickness of the CESL, it can be difficult to achieve the desired accuracy when using photo lithography to create the openings in the PSG layer to fabricate electrical contacts. With the reflectivity of the PSG layer widely varying, it can become impossible to predict the behavior of the light beams used in photo lithography, therefore, it may not be able to precisely place the location of the openings (or other physical characteristics such as size and depth) in the PSG layer. The desire is then to planarize the PSG layer as uniformly as possible to minimize variations in the thicknesses of the layer. It is possible to minimize thickness variations by maximizing surface uniformity in the two layers. Note that the discussion provided herein focuses on the CESL (an etch stop layer) and PSG (a dielectric layer) layer. However, this should not be construed as limiting the scope of the present invention to these two layers. The discussion can be extended to more than two layers without changing the spirit of the present invention.

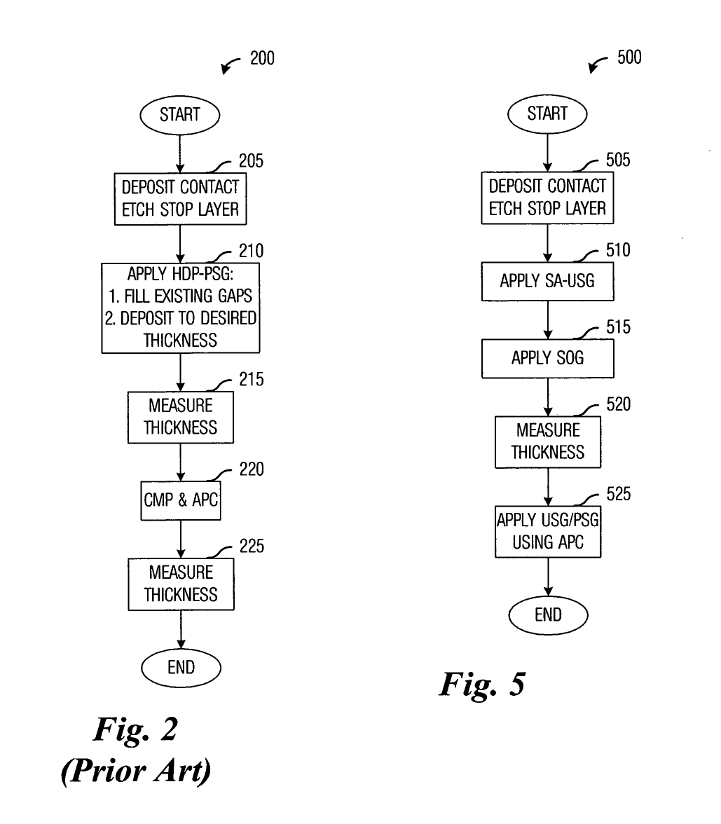

With reference now to FIG. 2, there is shown a flow diagram illustrating a prior art process 200 for planarization of the PSG layer to help minimize surface variations. The process 200 can be used to place and planarize the PSG layer (used as an interlayer dielectric layer) over devices fabricated on a substrate. The process 200 can begin after the devices have been fabricated on the substrate and prior to the fabrication of interconnections (metal layer(s)). After the devices have been fabricated on the substrate, a CESL can be deposited over the devices (block 205). The CESL can be used to protect the devices from the etching that will occur in subsequent fabrication steps. Once the CESL has been deposited, an interlayer dielectric layer (typically using PSG or alternatively, undoped-silicon glass (USG)), is deposited onto the substrate (block 210). The deposition of the interlayer dielectric layer can be made using high-density plasma chemical vapor deposition (HDP-CVD) techniques. The HDP-CVD technique (and other fabrication techniques mentioned in this discussion) is considered to be well understood by persons of ordinary skill in the art of the present invention and will not be discussed herein.

The deposition of the interlayer dielectric layer can occur in two steps. In a first step, the goal of the deposition of the interlayer dielectric layer is to fill in any existing gaps between devices. Since the devices are three dimensional, valleys (gaps) can be present between closely spaced devices and unless these valleys (gaps) are filled, electrical charge can readily travel from one device to another. After gaps have been filled in the first step, a second step can result in the deposition of an interlayer dielectric layer with a certain thickness, for example, nine-thousand Å. After the interlayer dielectric layer has been fabricated (block 210), the thickness of the interlayer dielectric layer can be measured (block 215). It can be necessary to measure the thickness of the interlayer dielectric layer deposited previously due to the relative imprecision of the HDP-CVD process. It may not be possible to adequately predict the thickness of the interlayer dielectric layer simply through the amount of time spent in the deposition process, so an actual measurement of the interlayer dielectric layer is necessary.

The thickness of the interlayer dielectric layer is needed to determine how much of the interlayer dielectric layer needs to be removed via chemical-mechanical polishing (CMP), which is used to planarize the interlayer dielectric layer (block 220). As discussed earlier, CMP uses both chemical and mechanical means to polish the interlayer dielectric layer. A polishing slurry, possibly containing both chemical solvents and polishing media, can be applied to the interlayer dielectric layer and then a mechanical polisher, typically a polishing wheel or belt, mechanically polishes the interlayer dielectric layer. The amount of polishing can be dependent upon the reactiveness and abrasiveness of the polishing slurry, the abrasiveness of the mechanical polisher, the amount of force applied by the mechanical polisher, the operating speed of the mechanical polisher, the amount of time spent polishing, the wear on the mechanical polisher, and so forth. Since there are many factors that can contribute to the effectiveness of the CMP process, an advanced process control (APC) may be needed to achieve accurate results. The APC may involve accurate timing controls of the CMP process as well as control over the polishing slurry and measurements of the thickness of the interlayer dielectric layer. Additionally, the APC can take into account the amount of time that the mechanical polisher (the polishing wheel or belt) has been in use since it was last replaced, the amount of time that the polishing slurry has been in use, and so on. This can be important because the effectiveness of the polish can depend on the amount of wear on the mechanical polisher as well as the frequency of reuse of the polishing slurry.

Even with the use of the APC, it can be relatively difficult to accurately predict the amount of dielectric material that has been removed from the interlayer dielectric layer. Therefore, after the CMP process (block 220), it may be necessary to once again measure the thickness of the interlayer dielectric layer (block 225). In addition to verifying the thickness of the interlayer dielectric layer and making sure that the thickness is within specifications, it may also be possible to measure the variation in the interlayer dielectric layer. After the interlayer dielectric layer has been planarized, the fabrication of the integrate circuit can continue to completion.

As discussed previously, disadvantages of the process 200 may include: thickness variation can still be significant after CMP planarization (with a non-uniformity of approximately 10 percent), the gap fill performance of the HDP-CVD process is not very good, charge damage and ultra-violet damage can occur to the CESL due to the HDP-CVD process, the HDP-CVD process can result in a reduction of the thickness of the CESL, the CMP process can be expensive due to expensive materials and multiple process steps, the thickness of the interlayer dielectric layer has to be measured both before and after the CMP process in order to obtain good performance, and the compression of the interlayer dielectric layer can result in the relaxation of the strained effect which was purposely applied to the substrate to obtain better driving current performance.

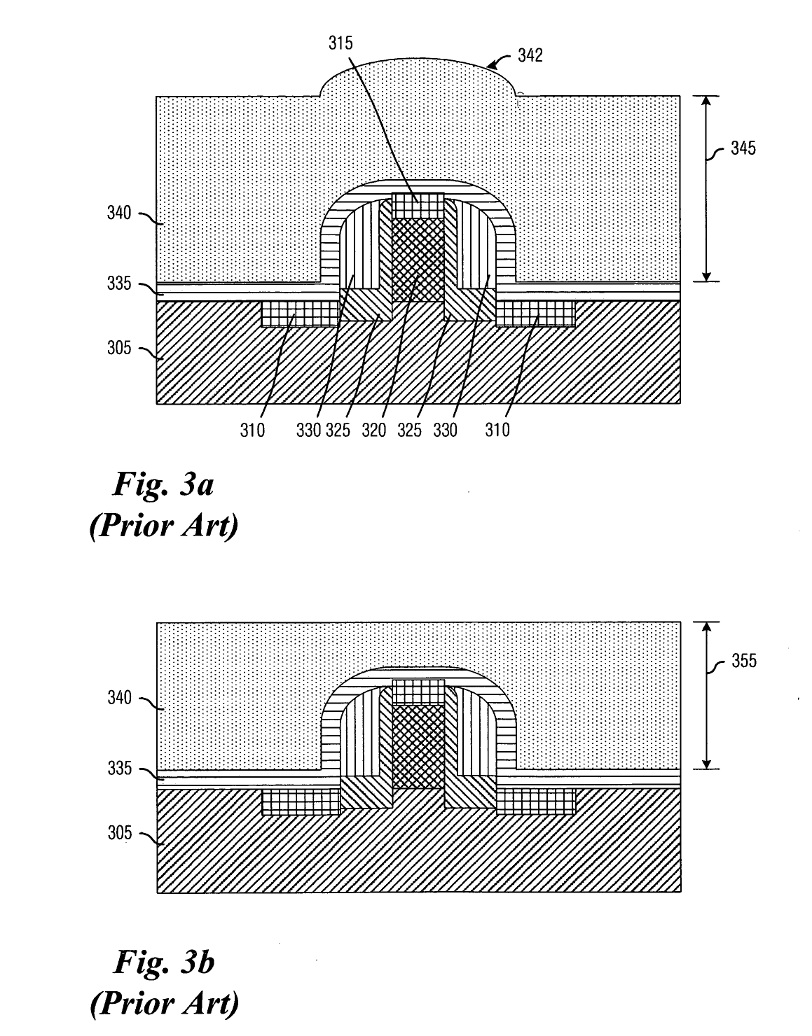

With reference now to FIGS. 3a and 3b, there are shown diagrams illustrating cross sectional views of a substrate containing a fabricated device with an interlayer dielectric layer which is shown pre and post planarization, wherein a prior art planarization process, such as the process 200 displayed in FIG. 2, is used to minimize variations in the thickness of the interlayer dielectric layer. FIG. 3a illustrates a substrate 305 containing a fabricated device prior to planarization. The fabricated device comprises a pair of source/drain terminals 310 and a gate terminal 315, with a poly-silicon gate 320. A spacer, comprised of an oxide region 325 and a silicon nitride region 330, can be used to effectively control the channel length. The spacer can also be referred to as an isolation area.

A contact etch stop layer (CESL) 335, applied over the fabricated device, can be used to prevent the propagation of an etch from damaging the fabricated device. An interlayer dielectric layer 340 can then be deposited over the fabricated device. As an example, in a modern fabrication process, phosphorous-doped silicon glass (PSG) or undoped silicon glass (USG) can be used as the material for the interlayer dielectric layer 340 and can be applied via a high-density plasma chemical vapor deposition (HDP-CVD) process. Note that due to the three-dimensional properties of the fabricated device, a bump 342 may be present in the interlayer dielectric layer. Note that for purposes of planarization, the interlayer dielectric layer 340 can be applied to a thickness (shown as span 345) that may be greater than the actual desired thickness since the CMP process can result in a reduction of the thickness of the interlayer dielectric layer 340. For example, the interlayer dielectric layer 340 can be applied to a thickness of approximately nine-thousand Å.

With reference now to FIG. 3b, a cross sectional view of the substrate after CMP planarization is provided. The polishing of the interlayer dielectric layer 340 is shown to be successful in eliminating bumps due to the topology of the fabricated devices (such as the bump 342 (FIG. 3a)). Furthermore, the polishing of the interlayer dielectric layer 340 has reduced the thickness of the interlayer dielectric layer 340. For example, the interlayer dielectric layer 340 has been reduced in thickness from approximately nine-thousand Å down to approximately five-thousand Å (shown as span 355).

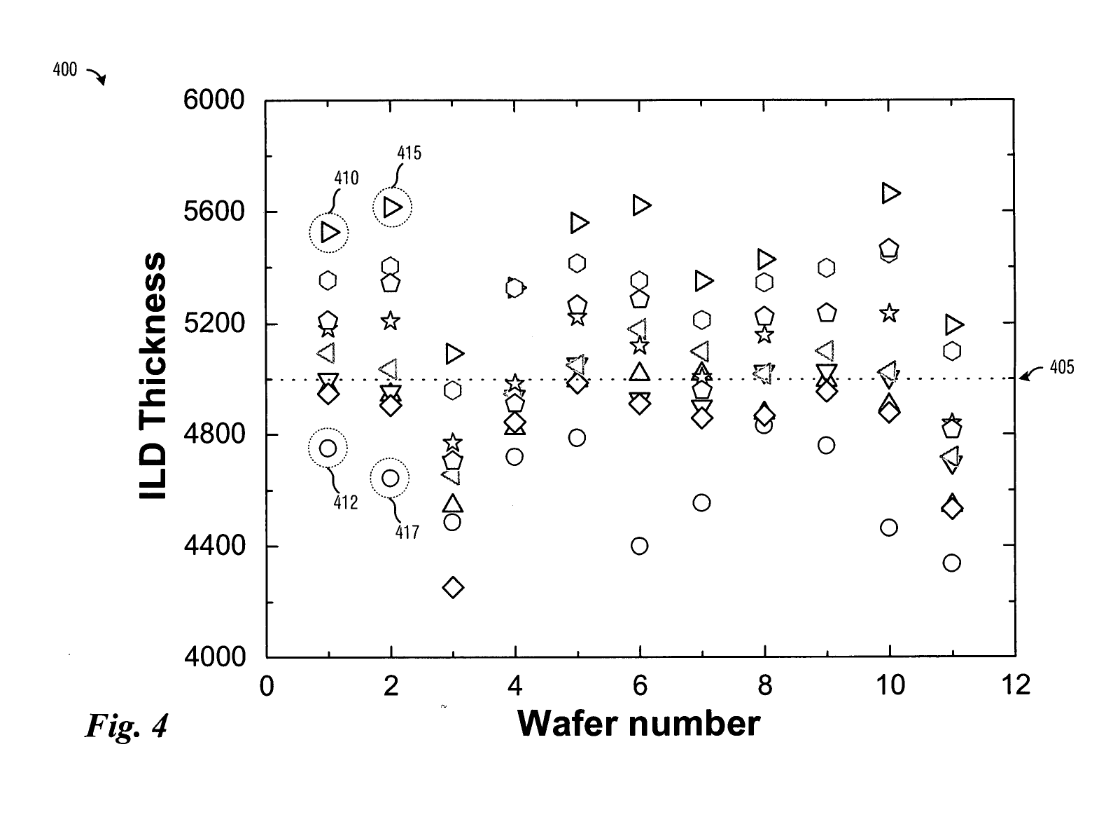

With reference now to FIG. 4, there is shown a diagram illustrating a data plot 400 of interlayer dielectric layer thicknesses for a number of wafers. The data plot 400 shows the thickness of an interlayer dielectric layer (such as the interlayer dielectric layer 340 (FIG. 3b)) after CMP planarization for several different wafers. The target thickness of the interlayer dielectric layer for the wafers shown in FIG. 4 is five-thousand Å (shown as dashed horizontal line 405). For wafer #1, a maximum interlayer dielectric layer thickness of approximately 5600 Å (data point 410) and a minimum interlayer dielectric layer thickness of approximately 4700 Å (data point 412) was determined. Wafer #1 then has a thickness variation of approximately 900 Å, or 18 percent. For wafer #2, a maximum thickness of 5600 Å (data point 415) and a minimum thickness of 4600 Å (data point 417) was found, for a thickness variation of 20 percent.

Clearly, the use of CMP to planarize the interlayer dielectric layer does not yield very good results. The resulting interlayer dielectric layer, while smoother than an interlayer dielectric layer that has not been planarized, retains significant variations, possibly enough to result in the fabrication of poor quality contacts.

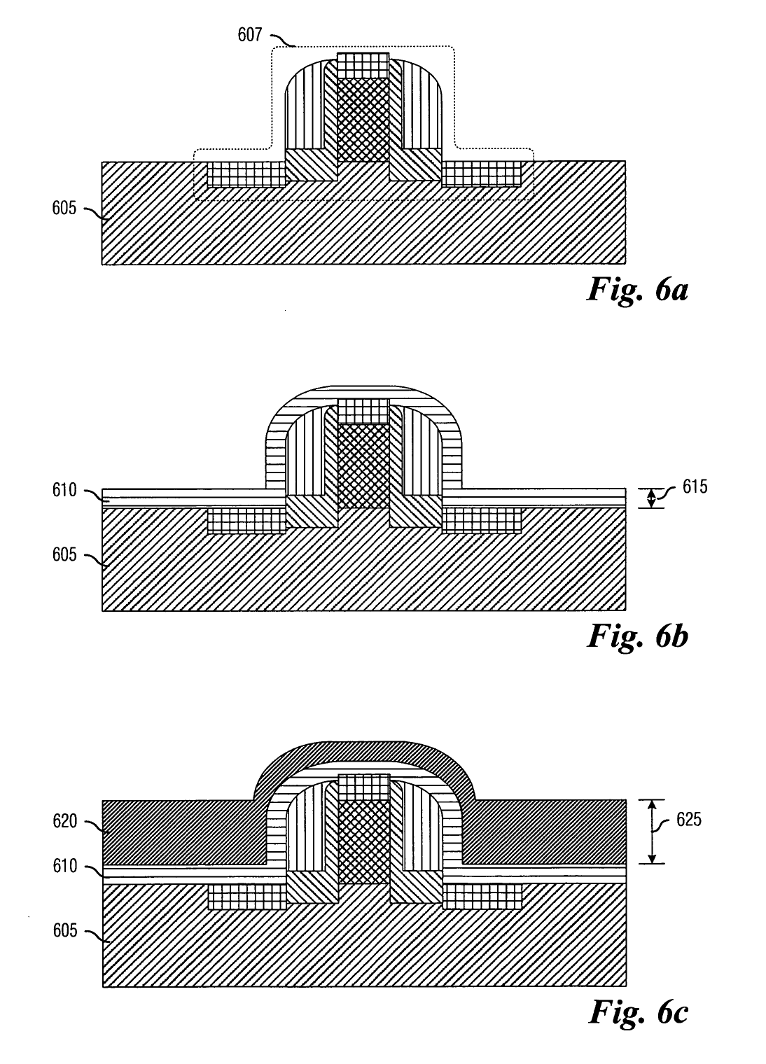

With reference now to FIG. 5, there is shown a flow diagram illustrating a process 500 for planarization of an interlayer dielectric layer to help minimize surface variations, according to a preferred embodiment of the present invention. Similar to the process 200 (discussed previously), the process 500 can be used to place and planarize an interlayer dielectric layer above fabricated devices to help minimize surface variations. Note that in the case of the process 500, the interlayer dielectric layer may comprise four layers of dielectric material. Furthermore, it can be possible to use an arbitrary number of layers without changing the spirit of the present invention.

The process 500 can begin after the devices have been fabricated onto a substrate and prior to the fabrication of interconnections (electrical connectors) between the devices. After the fabrication of the devices, a CESL can be deposited over the devices (block 505). According to a preferred embodiment of the present invention, silicon nitride (e.g. SiNₓ, x is less than about 2) can be used as the CESL layer and can be deposited using either low-pressure chemical vapor deposition (LP-CVD) or plasma enhanced chemical vapor deposition (PE-CVD) techniques. However, other materials can be used as the CESL layer as long as they react sufficiently differently to the etch material used to etch the interlayer dielectric layer (specifically, they are relatively inactive to the etch material) so that they can protect the devices and the substrate from the etch material.

After the deposition of the CESL, a second layer of a multilayer interlayer dielectric layer can be formed on top of the CESL. Initially, a first interlayer dielectric layer can be deposited (block 510). The first dielectric layer can be used to specifically cover the devices, which are lying on top of the substrate. The first dielectric layer can fill in any gaps between devices on the substrate, electrically isolating the devices. The first dielectric layer can be formed using undoped silicon glass (USG) using a sub-atmospheric pressure deposition technique (SA-USG) or an atmospheric pressure deposition technique (AP-USG).

After the deposition of the first dielectric layer, a second dielectric layer can be deposited (block 515). The second dielectric layer can be used to help fill out any significant surface irregularities that can be present in the first dielectric layer, such as bumps due to the topology of the devices present on the substrate. The second dielectric layer can be formed using spin-on-coating deposition such as spin on glass (SOG) techniques which has a benefit of the use of centrifugal force to help uniformly distribute the dielectric material across the wafer and can be made from USG. This can produce a dielectric layer with a low variation in overall thickness.

After the formation of the first and the second dielectric layers (blocks 510 and 515), a measurement of the thickness of the two dielectric layers can be made (block 520). A thickness measurement may be made to determine the thicknesses of the two dielectric layers already deposited and to determine how much more dielectric material needs to be deposited to bring the total thickness of the multilayer interlayer dielectric layer to a desired thickness. After the measurement of the thickness of the two dielectric layers, a third dielectric layer can be deposited (block 525). According to a preferred embodiment of the present invention, the third dielectric layer can be used to bring the multilayer interlayer dielectric layer to a desired thickness and can be made from phosphorous doped silicon glass (PSG) or USG and can be deposited using PE-CVD in conjunction with an APC. Since the PE-CVD technique can be highly precise and the thickness of the material deposited using the technique can be accurately predicted based upon the amount of time the technique is used, the APC used to control the deposition of the third dielectric layer can be based solely on the time that the technique is used.

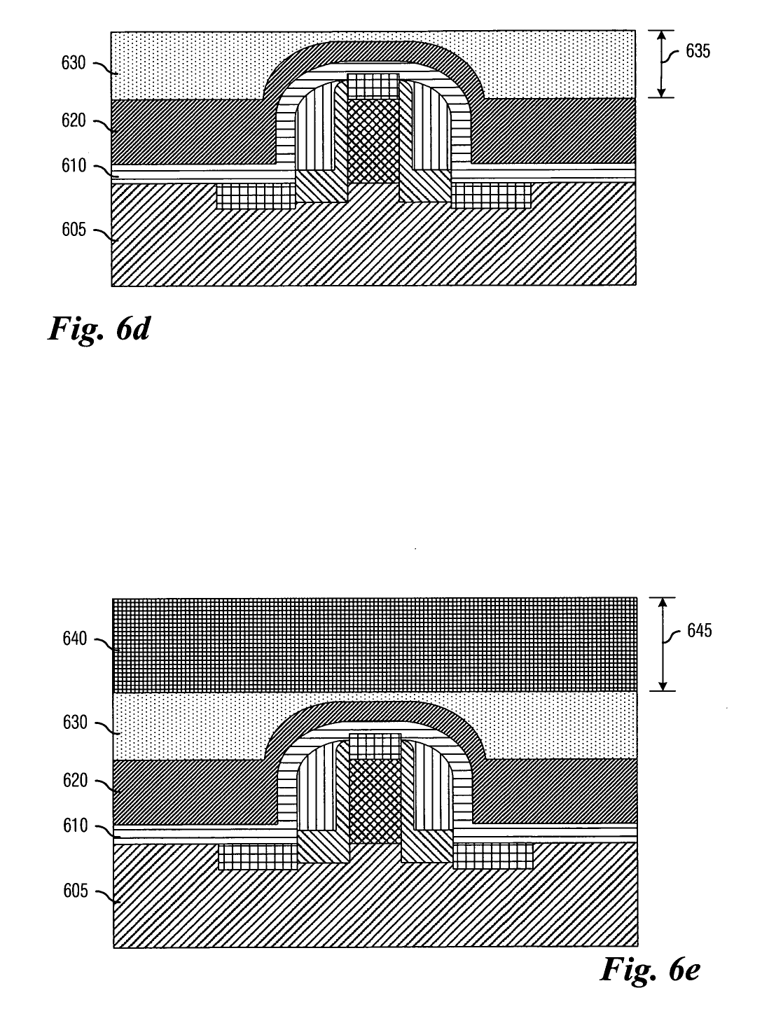

With reference now to FIGS. 6a through 6e, there are shown diagrams illustrating cross sectional views of a substrate containing a fabricated device at differing stages in the formation of a multilayer interlayer dielectric layer, wherein the fabrication of the multilayer interlayer dielectric layer produces an interlayer dielectric layer with a low degree of surface variations, according to a preferred embodiment of the present invention. FIG. 6a illustrates a substrate 605 with a device 607 fabricated on its surface. According to a preferred embodiment of the present invention, the device 607 may be a metal-oxide semiconductor field effect transistor (MOSFET) device with a gate length of less than 130 nm. However, the device 607 may be one of a wide variety of different devices or MOSFETs with other gate lengths. Furthermore, the MOSFETs should have an overall height of no more than 200 nm. Note that while a single device is shown on the surface of the substrate 605, in practice, the substrate 605 could any number of devices fabricated on its surface, with an upper limit being determined by the size of each device and the total surface area of the substrate 605. It is not uncommon for a substrate to contain tens of millions of devices.

After the device 607 has been fabricated on the surface of the substrate 605, it becomes necessary to provide electrical connections to and from the device 607. However, electrical connections cannot simply be placed on top of the device, namely a multilayer interlayer dielectric layer needs to be formed between the device 607 and the electrical connections to protect the device 607 from the electrical connections and the processing needed to fabricate the electrical connections. FIG. 6b illustrates a first step in creating the multilayer interlayer dielectric layer, which is to place a CESL layer 610 over the device 607 (as discussed in block 505 of FIG. 5). The CESL layer 610 can be deposited over the substrate 605 and the device 607 using a LP-CVD or a PE-CVD process. According to a preferred embodiment of the present invention, the CESL layer 610 can be deposited under the following conditions: the substrate 605 can be in an environment with nitrogen gas with silicon atoms at a temperature ranging from 300 to 550 degrees Celsius, the deposition pressure can vary from 0.5 to 5 Torr, and NH3 gas (ammonia) can be present. Under the listed conditions, the resulting CESL layer 610 can have a reflective index (RI) of 1.90 to 2.05 for light with a 633 nm wavelength and a RI of 2.10 to 2.70 for light with a 193 nm wavelength and a percentage of hydrogen ranging from 10 to 22 percent, with a step coverage (a measure of the ability to cover discontinuities in the substrate 605) from 70 to 100 percent and a thickness from 200 to 800 Å (shown as span 615) and a non-uniformity of less than two percent. The thickness of the CESL layer 610 should be dependent upon a requirement of the strained effect and can have a thickness ranging from 150 to 1000 Å. The strained effect can be used to improve on and off current performance and is considered to be well understood by those of ordinary skill in the art of the present invention. Note however, that the CESL layer 610 can be deposited using a wide variety of conditions with a CESL layer that is functionally effective.

After the formation of the CESL layer 610, a first dielectric layer 620 of the multilayer interlayer dielectric layer can be formed. FIG. 6c illustrates a second step in creating the multilayer interlayer dielectric layer, which is to place the first dielectric layer 620 over the CESL layer 610 (as discussed in block 510 of FIG. 5). The first dielectric layer 620 can be deposited over the CESL layer 610 using an AP-CVD or a SA-CVD process. According to a preferred embodiment of the present invention, the first dielectric layer 620 is made from USG can be deposited under the following conditions: the substrate 605 can be in an environment containing tetraethyl orthosilicate gas (TEOS) at a temperature of less than 550 degrees Celsius with the presence of oxygen. Under the above conditions, the resulting first dielectric layer 620 can have excellent gap-fill abilities with a gap-fill height on the order of the poly-silicon material 320 (FIG. 3a), a low overall film stress on the underlying structure, and a thickness of approximately 2500 Å (shown as span 625). The thickness of the first dielectric layer 620 can have an upper limit. The upper limit upon the thickness of the dielectric layer 620 on the isolation area (shown in FIG. 3a and is comprised of the oxide region 325 and the silicon nitride region 330) should be less than the sum of a height of the poly-silicon gate 320 (FIG. 3a) and 500 Å. In addition to the maximum thickness constraint, the CESL 610 and the first dielectric layer 620 can be constrained to having a thickness ratio ranging from 0.06 to 0.90 (CESL 610 to first dielectric layer 620 thickness). The material used in the fabrication of the CESL layer 610 can have a given dielectric constant and a given reflectivity index, denoted DC_{CESL} and RI_{CESL}, as should the material used in the fabrication of the first dielectric layer 620, denoted DC_{FDL} and RI_{FDL}. Note however that a first dielectric layer can be deposited using a wide variety of conditions and the resulting first dielectric layer can be substantially equivalent functionally.

After the formation of the first dielectric layer, a second dielectric layer 630 can be formed. FIG. 6d illustrates a third step in creating the multilayer interlayer dielectric layer, which is to place the second dielectric layer 630 over the first dielectric layer 620 (as discussed in block 515 of FIG. 5). According to a preferred embodiment of the present invention, the second dielectric layer 630 is made from USG can be deposited over the first dielectric layer 620 using a spin on glass (SOG) technique. The SOG technique typically involves the application of a material (such as a silicate or siloxane) onto the substrate 605, which can be on a device that spins the substrate 605 at a given rate, and the centrifugal force results in a uniform distribution of the material across the surface of the substrate 605. According to a preferred embodiment of the present invention, the second dielectric layer 630 can be deposited under the following conditions: a silicate or siloxane material is used for the creation of the second dielectric layer 630, which is applied in a liquid form on the substrate 605. The substrate 605 is spun at a rate of between 150 to 500 revolutions per minute and may undergo pre-baking processing with a temperature range of 80 to 320 degrees Celsius and a hot-backing processing with a temperature range of 400 to 450 degrees Celsius. The resulting second dielectric layer 630 can have a thickness of approximately 500 Å (shown as span 635) and a non-uniformity of less than two (2) percent while the overall non-uniformity of the multilayer interlayer dielectric layer (comprising the CESL layer 610, the first dielectric layer 620, and the second dielectric layer 630) is less than three (3) percent. As with the CESL layer 610 and the first dielectric layer 620, there can be an upper limit on the second dielectric layer 630, with the upper limit being that the sum of the thicknesses of the CESL layer 610, the first dielectric layer 620, and the second dielectric layer 630 being less than the height of the poly-silicon gate 320 and three-thousand Å. The first and the second dielectric layers 620 and 630 may be considered to be a single dielectric layer made from USG. The combined thickness of the first and the second dielectric layers 620 and 630 can be optimally constrained to being 1.1 to 15 times the thickness of the CESL 610. The material used to fabricate the second dielectric layer 630 can have a given dielectric constant and a reflectivity index, denoted DC_{SDL} and RI_{SDL}, respectively. According to a preferred embodiment of the present invention, the dielectric constants and the reflectivity indexes of the materials used in the CESL layer 610, the first dielectric layer 620, and the second dielectric layer 630 should have the following relationships: DC_{CESL}>DC_{SDL}>DC_{FDL} and RI_{CESL}>RI_{FDL}>RI_{SDL}. Once again, a second dielectric layer can be deposited using other techniques and under different conditions using the SOG technique with the resulting second dielectric layer having similar functionality.

After the completion of the second dielectric layer 630, the overall thickness layer of the multilayer interlayer dielectric layer can be measured (as discussed in block 520 of FIG. 5). With the measurement of the thickness of the multilayer interlayer dielectric layer, the thickness of a third dielectric layer 640 can be determined. According to a preferred embodiment of the present invention, the third dielectric layer 640 can be used to bring the overall thickness of the multilayer interlayer dielectric layer to a desired value. Therefore, the thickness of the third dielectric layer 640 can be determined to be a difference between the desired overall thickness of the multilayer interlayer dielectric layer and the thickness of the first dielectric layer 620 and the second dielectric layer 630.

FIG. 6e illustrates a fifth step in creating the multilayer interlayer dielectric layer, which is to place the third dielectric layer 640 over the second dielectric layer 630 (as discussed in block 525 of FIG. 5). The third dielectric layer 640 can be deposited over the second dielectric layer 630 using a PE-CVD or HDP-CVD process. According to a preferred embodiment of the present invention, the third dielectric layer 640 is made from PSG (note however, that USG can be used for the third dielectric layer 640) and can be deposited under the following conditions: the substrate 605 can be in an environment containing a gas with silicon, phosphorous, and oxygen atoms. If the PE-CVD process is used in the deposition of the third dielectric layer 640, then argon gas (containing silicon, phosphorous, and oxygen atoms) is used to sputter the SOG surface of the second dielectric layer 630. If the HDP-CVD process is used, then a pre-heated oxygen gas (containing silicon, phosphorous, and oxygen atoms) is used to sputter the SOG surface of the second dielectric layer 630. During the CVD (either PE-CVD or HDP-CVD) process, an APC application is used to control the thickness of the third dielectric layer 640. The APC application can monitor the duration of the CVD process to determine the thickness of the third dielectric layer 640 due to the precision of the deposition process. The above processing conditions can result in the third dielectric layer having a thickness of approximately two-thousand (2000) Å (shown as span 645) and a non-uniformity of less than two (2) percent. Unlike the CESL layer 610, the first dielectric layer 620, and the second dielectric layer 630, there may not be an upper limit on the thickness of the third dielectric layer 640. However, the thickness of the third dielectric layer 640 should be limited so that the overall thickness of the multilayer interlayer dielectric layer should meet the desired thickness. Again, a third dielectric layer can be deposited using other techniques and under different conditions using either the PE-CVD or HDP-CVD techniques with the resulting third dielectric layer having similar functionality and thickness.

The completed multilayer interlayer dielectric layer fabricated under the preferred conditions of a preferred embodiment of the present invention (as discussed previously and as shown in FIG. 6e) can have an overall thickness of approximately five-thousand (5000) Å (wherein the first dielectric layer 620 is approximately 2.5-thousand Å, the second dielectric layer 630 is approximately 500 Å, and the third dielectric layer 640 is approximately two-thousand Å) with an overall non-uniformity of less than four (4) percent (the first dielectric layer 620 has a non-uniformity of less than two (2) percent, the second dielectric layer 630 has a non-uniformity of less than two (2) percent, and the third dielectric layer 640 has a non-uniformity of less than two (2) percent). In addition to the upper limits placed upon the thicknesses of the various layers of the multilayer interlayer dielectric layer (as discussed previously), an additional constraint can be placed upon the thicknesses of the layers of the multilayer interlayer dielectric layer to help optimize the reflectivity index of the multilayer interlayer dielectric layer.

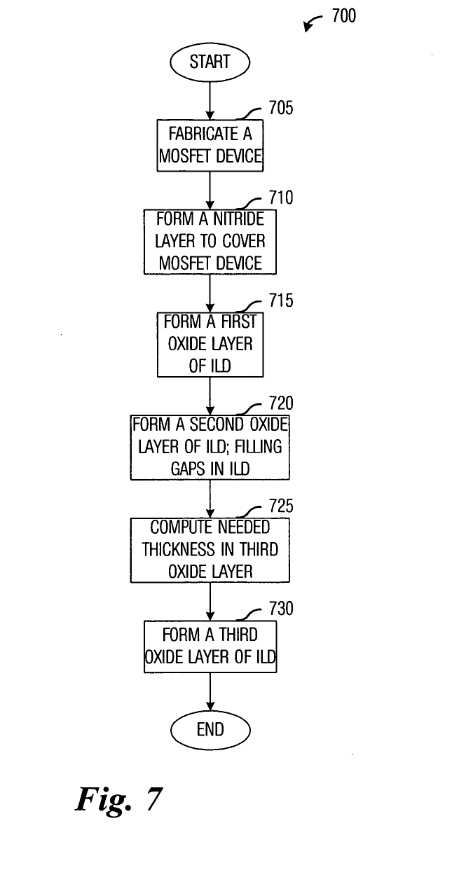

With reference now to FIG. 7, there is shown a flow diagram illustrating a process 700 for fabricating a semiconductor device, according to a preferred embodiment of the present invention. According to a preferred embodiment of the present invention, the process 700 can begin after a substrate has been created and prepared for use in the fabrication of a semiconductor device and is part of a longer process for fabricating the semiconductor device. The fabrication of the semiconductor device can proceed with additional processing steps after the completion of the process 700 as shown in FIG. 7. The process 700 can begin by fabricating a device(s), preferably a MOSFET device, on the substrate (block 705). The fabrication of the device(s) can involve several processing steps, but is simplified into a single process step. Once the device(s) has been fabricated, a protective layer (a nitride layer) can be formed over the device(s) (block 710). The nitride layer covers the device(s) and can be used to protect the device(s) from subsequent process steps involved in the fabrication of the semiconductor device. According to a preferred embodiment of the present invention, the nitride layer can be formed using either a LP-CVD or PE-CVD process.

After forming the nitride layer (block 710), a first oxide layer can be formed over the nitride layer (block 715). The first oxide layer can be an initial layer of a multilayer interlayer dielectric, wherein the first oxide layer can be formed using either a SA-CVD or an AP-CVD process. Following the formation of the first oxide layer, a second oxide layer can be formed (block 720). The second oxide layer's primary function can be to fill in any existing gaps in the first oxide layer, which may have arisen due to the three-dimensional topology of the device(s). The second oxide layer can be formed using a SOG process, which can help produce an oxide layer with good gap-fill properties. With the formation of the first and the second oxide layers, an algorithm can be used to compute a thickness of a third oxide layer (block 725). According to a preferred embodiment of the present invention, the algorithm can be an advanced process control application that can be used to determine the thickness of the first and the second oxide layers and the compute the thickness of the third oxide layer based upon the determined thickness and a desired thickness of the first, second, and third oxide layers. Since a process used to form the third oxide layer is very precise, there is a direct relationship between the thickness of the third oxide layer and the amount of time spent in forming the third oxide layer. After computing the needed thickness for the third oxide layer, the third oxide layer can be formed, preferably using either a PE-CVD or HDP-CVD process (block 730).

Although the present invention and its advantages have been described in detail, it should be understood that various changes, substitutions and alterations can be made herein without departing from the spirit and scope of the invention as defined by the appended claims. The third dielectric layer can be used to specifically perform the operation of gap filling, i.e., filling the valleys between devices to ensure that the devices are electrically isolated.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A multilayer interlayer dielectric (MID) for a semiconductor device, wherein the semiconductor device comprises a field effect transistor (FET) and a substrate, the MID comprising:
a first thickness of the MID covering the FET;
a second thickness of the MID over the first thickness of the MID;
wherein a thickness ratio of the first thickness of the MID to the second thickness of the MID ranges from about 0.06 to about 0.90; and
wherein the MID further comprises a third thickness and a fourth thickness.

2. The MID of claim 1, wherein a thickness of the second thickness is less than about a sum of a thickness of a gate electrode of the FET and five hundred Angstroms.

3. The MID of claim 2, wherein the second thickness is created using a sub-atmospheric chemical vapor deposition process and is tetraethyl orthosilicate gas (TEOS) based.

4. The MID of claim 1, wherein a sum of a thickness of the first thickness, a thickness of the second thickness, and a thickness of the third thickness is less than about a sum of a thickness of a gate electrode of the FET and three-thousand Angstroms.

5. The MID of claim 1, wherein the third thickness is created using a flowable dielectric material.

6. The MID of claim 1, wherein the fourth thickness is a doped dielectric layer with a thickness of more than about three hundred Angstroms.

7. The MID of claim 6, wherein the fourth thickness is created from a phosphorous doped glass material.

8. The MID of claim 1, wherein the materials used in the first thickness, the second thickness, and the third thickness have a dielectric constant, wherein a relationship between the dielectric constants of the materials can be expressed as:
DC_{FT}>DC_{TT}>DC_{ST}
wherein DC_{FT} is a dielectric constant of the first thickness, DC_{ST} is a dielectric constant of the second thickness, and DC_{TT} is a dielectric constant of the third thickness.

9. The MID of claim 1, wherein the materials used in the first thickness, the second thickness, and the third thickness have a reflectivity index, wherein a relationship between the dielectric constants of the materials can be expressed as:
RI_{FT}>RI_{ST}>RI_{TT}
wherein RI_{FT} is a reflectivity index of the first thickness, RI_{ST} is a reflectivity index of the second thickness, and RI_{TT} is a reflectivity index of the third thickness.

10. A multilayer interlayer dielectric (MID) for a semiconductor device, wherein the semiconductor device comprises a field effect transistor (FET) and a substrate, the MID comprising:
a nitrogen-containing layer over the FET;
at least one oxygen-containing layer;
wherein a thickness ratio of a thickness of the oxygen-containing layer to a thickness of the nitrogen-containing layer ranges from about 1.1 to about 15; and
wherein the MID contains at least four layers.

11. The MID of claim 10, wherein a thickness of the second thickness is less than about a sum of a thickness of a gate electrode of the FET and five hundred Angstroms.

12. The MID of claim 11, wherein the second thickness is created using a sub-atmospheric chemical vapor deposition process and is tetraethyl orthosilicate gas (TEOS) based.

13. The MID of claim 10, wherein a sum of a thickness of the first thickness, a thickness of the second thickness, and a thickness of the third thickness is less than about a sum of a thickness of a gate electrode of the FET and three-thousand Angstroms.

14. The MID of claim 10, wherein the fourth thickness is a doped dielectric layer with a thickness of more than three hundred Angstroms.

15. The MID of claim 14, wherein the fourth thickness is created from a phosphorous doped glass material.

16. The MID of claim 10, wherein the oxygen-containing layer comprises two undoped oxide layers, wherein a first undoped oxide layer is fabricated using a sub-atmospheric chemical vapor deposition (SA-CVD) process and a second undoped oxide layer is fabricated using a spin-on-coating process.

17. A method for fabricating a semiconductor device, the method comprising:
forming a field effect transistor (FET) device on a semiconductor substrate;
forming a first nitride layer over the semiconductor substrate;
forming a first oxide layer over the first nitride layer;
forming a second oxide layer over the first oxide layer;
computing a thickness of a third oxide layer; and
forming the third oxide layer over the second oxide layer.

18. The method of claim 17, wherein the first nitride layer covers the FET device, and wherein the first nitride layer is formed using a low-pressure chemical vapor deposition (LP-CVD) or a nitrogen plasma containing process.

19. The method of claim 17, wherein the first oxide layer is formed using either a sub-atmospheric pressure chemical vapor deposition (SA-CVD) or an atmospheric pressure chemical vapor deposition (AP-CVD) process.

20. The method of claim 17, wherein the second oxide layer is formed using a spin-on-coating process.

21. The method of claim 17, wherein the computing comprises determining the thickness of the third oxide layer by measuring a thickness of the first oxide layer and a thickness of the second oxide layer and subtracting the thickness of the first oxide layer and the thickness of the second oxide layer from a desired thickness for all three oxide layers.

22. The method of claim 17, wherein the third oxide layer is formed using a high-density plasma chemical vapor deposition process.
